(19) United States
(12) Patent Application Publication
(10) Pub. No.: US 2007/0063767 A1
(43) Pub. Date: Mar. 22, 2007

(54) Bypassable low noise amplifier topology with multi-tap transformer

(75) Inventor: Amitava Das, Palatine, IL (US)

Correspondence Address: BRINKS HOFER GILSON & LIONE, P.O. BOX 10395, CHICAGO, IL, 60610, US

(73) Assignee: FREESCALE SEMICONDUCTOR, INC.

(21) Appl. No.: 11/210,315

(22) Filed: Aug. 24, 2005

(51) Int. Cl. H03F 1/14

(52) U.S. Cl. 330/51

(57) ABSTRACT

An amplifier is disclosed that contains a transistor (BJT), a switch (MOSFET), and a transformer. The collector of the BJT is connected to an end of the transformer while the base of the BJT is connected to a point between the ends of the transformer through the MOSFET. When the amplifier is in an active mode in which the amplifier has gain, signals supplied to the amplifier are provided to the transformer through the BJT. When the amplifier is in a bypass mode in which the amplifier does not have gain, signals supplied to the amplifier are provided to the transformer through the MOSFET and the BJT is turned off. The amplifier is designed such that the amplifier characteristics are optimized and then the MOSFET is connected to the transformer such that the input impedance of the amplifier is independent of the mode.

### TECHNICAL FIELD

The present application relates to a low noise amplifier. More specifically, the present application relates to a bypassable low noise amplifier containing a transformer with one or more taps.

### BACKGROUND

The variety and use of electronic devices, especially portable electronic devices such as cellular telephones, laptop computers, and personal digital assistants (PDAs), has dramatically increased in recent years. Many electronic devices, in addition, communicate with other electronic devices. For example, cellular telephones use base stations to rout and amplify data transmission. When designing communication devices used in portable electronic devices, various considerations are taken into account when designing the transmitter and receiver used for transmitting and receiving signals containing the data.

One such consideration is power consumption, which affects battery lifetime. In the receiver of a portable electronic device, the received signals are provided to multiple modules, each of which consumes power when operational. One of these modules is a low noise amplifier. The amplifier is used to amplify the signals for further processing if the portable electronic device is far from the transmission origin (e.g. base station) to boost the signal strength to adequate levels to be used by downstream modules. If the portable electronic device is sufficiently close to the transmitter origin, the received signals may be strong enough such that gain provided by the amplifier may be reduced or eliminated. Regardless of the amount of gain, the input impedance of the amplifier, i.e. the amount of impedance experienced by the signals provided to the input, should be the same.

### BRIEF DESCRIPTION OF THE DRAWINGS

FIG. 1 shows circuits in an electronic device in accordance with an embodiment.

FIG. 2 illustrates a first embodiment of an amplifier.

FIG. 3 shows one embodiment of a method of providing an amplifier in accordance with an embodiment.

FIG. 4 illustrates a second embodiment of an amplifier.

FIG. 5 illustrates a third embodiment of an amplifier.

### DETAILED DESCRIPTION OF THE EMBODIMENTS

A low noise amplifier (LNA) is disclosed that contains an active stage, a bypass switch, and a transformer. In an active mode, when the amplifier provides gain to high frequency input signals supplied to the amplifier, the signals are supplied to the transformer through the active stage. In a bypass mode, when the amplifier does not provide gain to the input signals, the signals are supplied to the transformer through the bypass switch and the active stage is turned off. By judicious selection of the point of connection to the transformer by the bypass switch, the impedance in both the active mode and bypass mode can be equalized. In addition, as the active stage is turned off, the power consumed by the amplifier is reduced substantially.

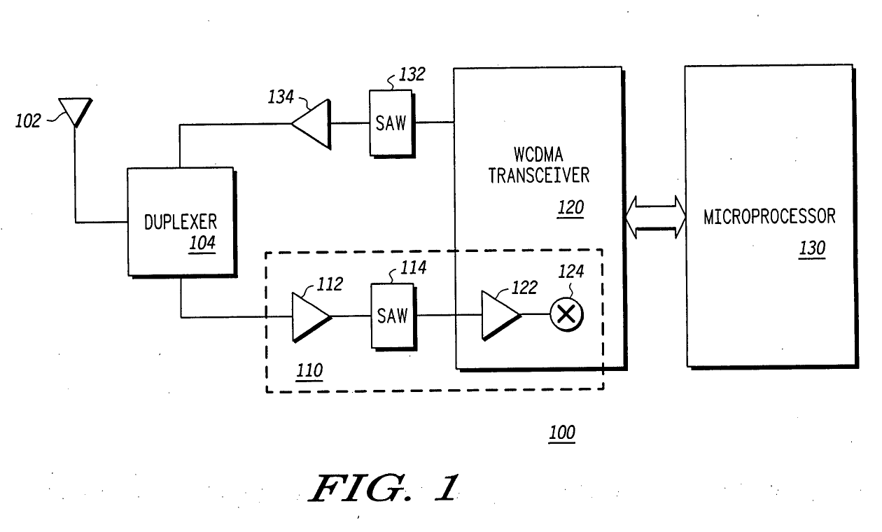

FIG. 1 illustrates an embodiment of a half-duplex electronic device 100 according to one embodiment of the present invention. The electronic device 100 may be a portable electronic device such as a cellular telephone, laptop computer, or personal digital assistant (PDAs). Other components are present within the electronic device 100 and well known to one of skill in the art, but are not shown in FIG. 1 for clarity. The electronic device 100 may be used in, for example, 3G W-CDMA communications (third generation wideband code division multiple access). W-CDMA can support mobile/portable voice, images, data, and video communications at high speeds of up to 2 Mbps (megabits per second). The input signals are digitized and transmitted in coded, spread-spectrum mode over a broad range of frequencies. A 5 MHz-wide carrier is used, compared with 200 KHz-wide carrier for narrowband CDMA.

As shown, the electronic device 100 contains an antenna 102 which receives input signals and transmits output signals. The input signals received by the antenna 102 are radio frequency (RF) signals that have a frequency in one of several ranges: 2110-2170, 1930-1990, or 869-894 MHz, for example.

The antenna 102 is connected to a duplexer 104 that selects whether input signals are to be received or output signals are to be transmitted by the electronic device 100. If input signals are to be received, the input signals are distributed to along a reception path 110. The reception path 110 contains an external low noise amplifier 112 connected to the duplexer 104 and a receiver SAW filter 114 connected to the low noise amplifier 112.

An internal low noise amplifier 122 of the reception path 110 is integrated within a transceiver 120 and is connected with the receiver SAW filter 114. The internal low noise amplifier 122 is connected with a mixer 124 integrated in the transceiver 120. The mixer 124 downconverts the RF signals to baseband signals of up to about a few MHz for further processing in the transceiver 120. The transceiver 120 communicates with a microprocessor 130. The transceiver 120 also supplies signals to the antenna 102 through a transmitter SAW filter 132, a power amplifier 134, and the duplexer 104.

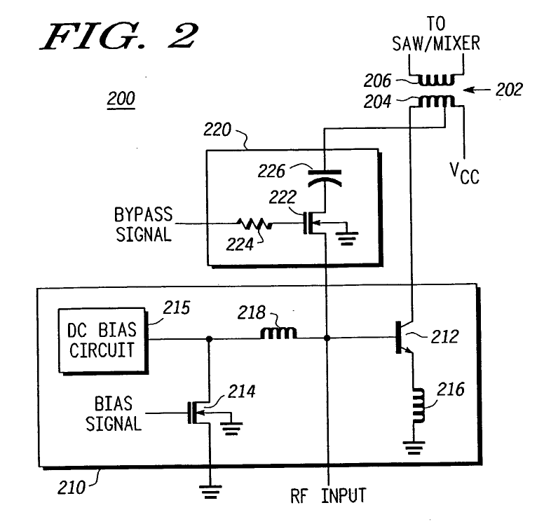

FIG. 2 illustrates an embodiment of a low noise amplifier of the present invention. The amplifier 200 may be either the external amplifier 112 or the internal amplifier 122. As shown in FIG. 2, the low noise amplifier 200 contains a transformer 202, an active stage 210 and a bypass stage 220. The amplifier 200 has two modes: an active mode, in which the amplifier 200 provides gain to RF input signals supplied to it, and a bypass mode, in which the amplifier 200 does not provide gain to the RF input signals.

The transformer 202 has an input coil 204 and an output coil 206. The output coil 206 is connected to the SAW filter 114 or the mixer 124. One end of the input coil 204 is connected to a power supply (not shown) and the other end is connected to the active stage 210.

The active stage 210 contains a bipolar junction transistor (BJT) 212, a DC bias circuit 215, a bias switch 214, and first and second inductors 216 and 218. As one example, the inductance of the inductor 216 is less than 1 nH, which gives an impedance of a few Ω in the frequency range of the input signals. The inductance of the transformer 202 is about 25-30 nH, which provides an impedance of a few tens of Ω. The overall impedance seen by the RF input signals entering the amplifier 200 is about 50 Ω.

The collector of the BJT 212 is connected to the other end of the input coil 204. The emitter of the BJT 212 is connected to ground through the first inductor 216. The RF input signals are supplied to the base of the BJT 212. The bias circuit 214 provides DC biasing to the base of the BJT 212 through the second inductor 218 such that the BJT 212 is on in the active mode and is off in the bypass mode. The second inductor 218 provides a large impedance to the input signals supplied to the base of the BJT 212 so that the input signals are supplied to the transformer 202 without substantial signal loss.

The bias switch 214, in the embodiment shown, is formed by a metal-oxide-semiconductor field effect transistor (MOSFET). The source of the MOSFET bias switch 214 is connected to ground, the drain is connected to the second inductor 218, and the gate is supplied with a bias on/off switch. The MOSFET bias switch 214 is turned on in the bypass mode such that one end of the second inductor 218 is grounded. The DC bias circuit 215 may be turned off in the bypass mode. Similarly, the MOSFET bias switch 214 is turned off in the active mode such that one end of the second inductor 218 is DC biased at the bias voltage provided by the DC bias circuit 215.

The bypass stage 220 contains bypass switch 222 formed by a MOSFET 222, a resistor 224, and a capacitor 226. The gate of the bypass switch 222 is supplied with a bypass signal through the resistor 224. The resistor 224 decreases the current supplied to the gate of the bypass switch 222 when the amplifier 200 enters the bypass mode. The source of the bypass switch 222 is connected to the base of the BJT 212 and the second inductor 218. The drain of the bypass switch 222 is connected to the input coil 204 of the transformer 202 through the capacitor 226, which blocks a DC voltage from being supplied to the transformer 202. More specifically, the drain of the bypass switch 222 taps the transformer 202 and is connected between the end of the input coil 204 connected to the BJT 212 and the end of the input 204 connected to the power supply.

When the amplifier 200 is in the active mode, the bypass switch 222 is turned off and the input signals are provided to the transformer 202 through the BJT 212. The BJT 212 provides gain for the input signals so that the output signals supplied to the mixer 106 are amplified. When the amplifier 200 is in the bypass mode, the BJT 212 is turned off and the input signals are provided to the transformer 202 through the bypass switch 222. In the embodiment shown in FIG. 2, the MOSFET acts merely as a switch to provide the input signals to the transformer 202 in the bypass mode and does not provide the input signals with gain.

Note that, as neither the BJT 212 nor the MOSFET 222 draws a significant amount of current in the bypass mode (on the order of a few nA) compared with the active mode (in which the BJT 212 draws a few μA), the amount of power consumed by the amplifier 200 in the bypass mode is small. In alternate embodiments, a MOSFET may be used in the gain stage rather than a BJT. Although a BJT provides a better noise figure than a MOSFET, the MOSFET consumes less power when active than the BJT.

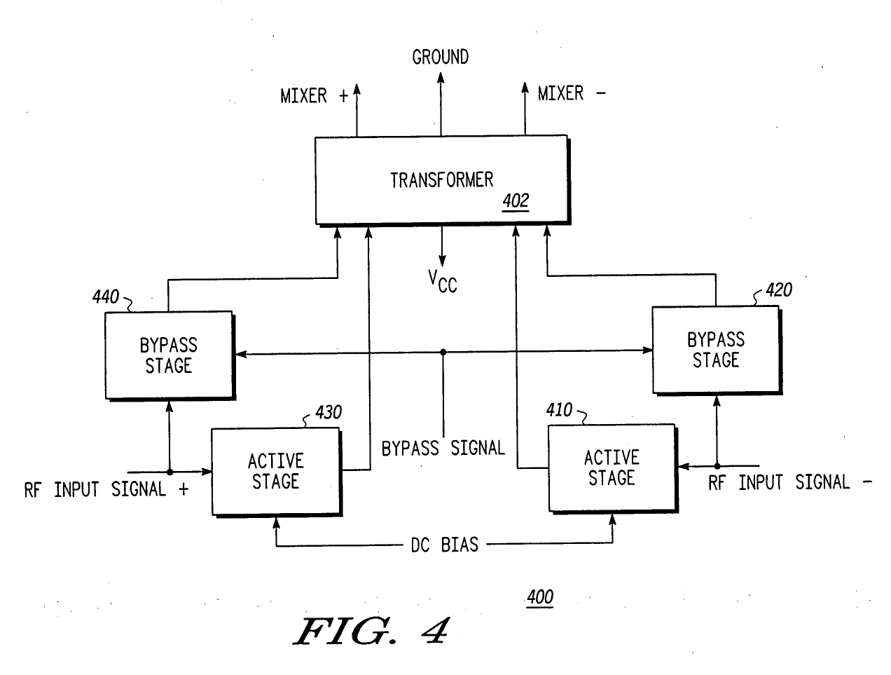

One method of producing the amplifier is shown in FIG. 4. After the start block 400, the amplifier is designed with desired gain stage characteristics, such as linearity, current drain, noise figure and input impedance in block 402. After fabricating the amplifier, the characteristics are measured in the active mode in block 404.

In block 406, the designer determines whether the characteristics are within a predetermined tolerance. If the characteristics are not within a predetermined tolerance, the amplifier design is tuned in block 408 and the characteristics are again tested in block 406. If the characteristics are within a predetermined tolerance, it is determined whether the bypass stage has been added in block 410.

If the bypass stage has not been added in block 410, the bypass stage is added in block 412 and the tap of the transformer (i.e. the position of the connection to the transformer) is selected in block 414. Once the tap is connected in block 414, the impedance is measured in the bypass mode in block 416. If the impedance is not matched between the active mode and the bypass mode, the tap is adjusted in block 420 and the impedance is measured again in block 416. If the impedance is matched such that the input impedance of the amplifier is independent of the mode, the characteristics of the amplifier are again measured in block 404 to confirm that the addition of the bypass stage has not altered the amplifier characteristics beyond the tolerance.

If the bypass stage has been added in block 410, the impedance is measured in the bypass mode in block 422 and it is determined in block 424 whether the input impedances in the bypass and active modes are matched. If the impedance is not matched, the tap is adjusted in block 426 and the impedance is measured again in block 422. If the impedance is matched in block 424, the amplifier meets specifications and the method ends in block 428.

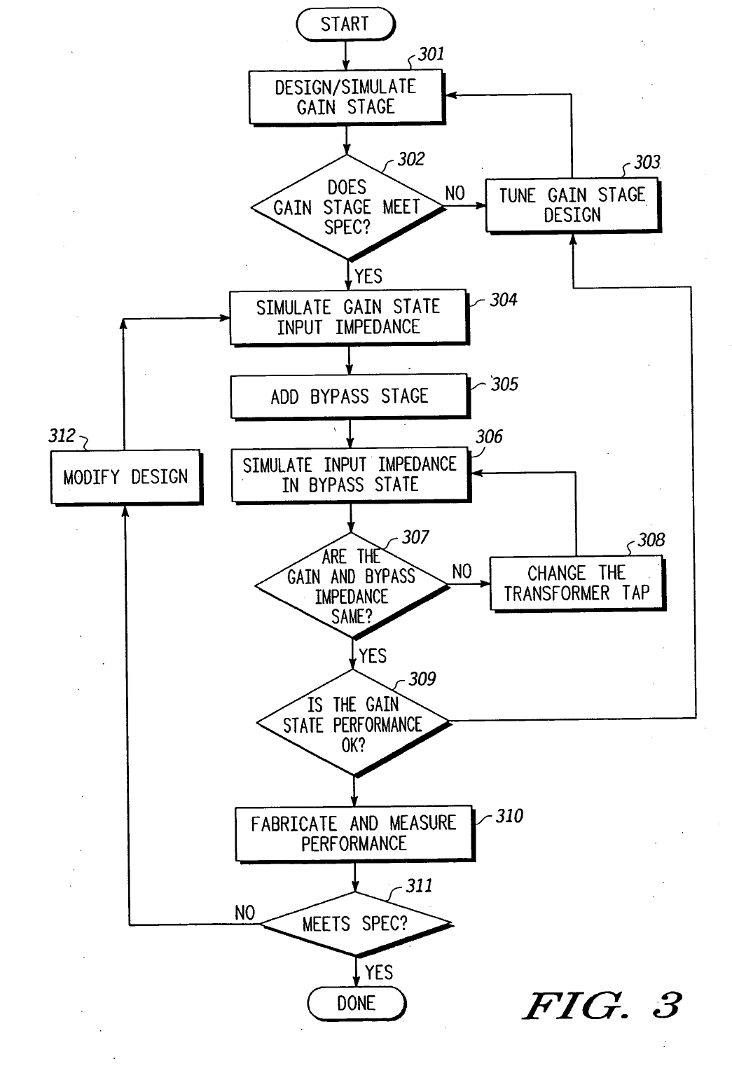

FIG. 3 illustrates one embodiment of a differential amplifier 300. The differential amplifier 300 contains a transformer 302, a pair of active stages 310 and 330, and a pair of bypass stages 320 and 340. Each of the first active stage 310 and the first bypass stage 320 is connected to different locations on one side of the transformer 302. The first and second active stages 310 and 330 are connected at ends of the transformer 302, symmetrically around the center of the transformer 302. Similarly, the first and second bypass stages 320 and 340 are connected symmetrically around the center of the transformer 302. The center of the input coil of transformer 302 is connected to power (Vcc), the center of the output coil of the transformer 302 is connected to ground, and the ends of the output coil are connected to SAW filters or to the inputs of a differential mixer (not shown).

The active stages 310 and 330 and bypass stages 320 and 340 are similar to the active stage 210 and bypass stage 220, respectively, and are fed by the same bypass and bias signals described in FIG. 2. As in the previous embodiment, the active stages 310 and 330 and bypass stages 320 and 340 are connected such that the impedance seen by the input signals is the same regardless of whether the amplifier 300 is in the active mode or the bypass mode.

The amplifier shown can be either provided in half-duplex electronic devices, as shown in FIG. 1 or in full duplex electronic devices. Full duplex electronic devices can transmit and receive at the same time while half-duplex duplex electronic devices can either transmit or receive, but cannot do both at the same time. Full duplex electronic devices contain multiple antennas, but do not contain a duplexer.

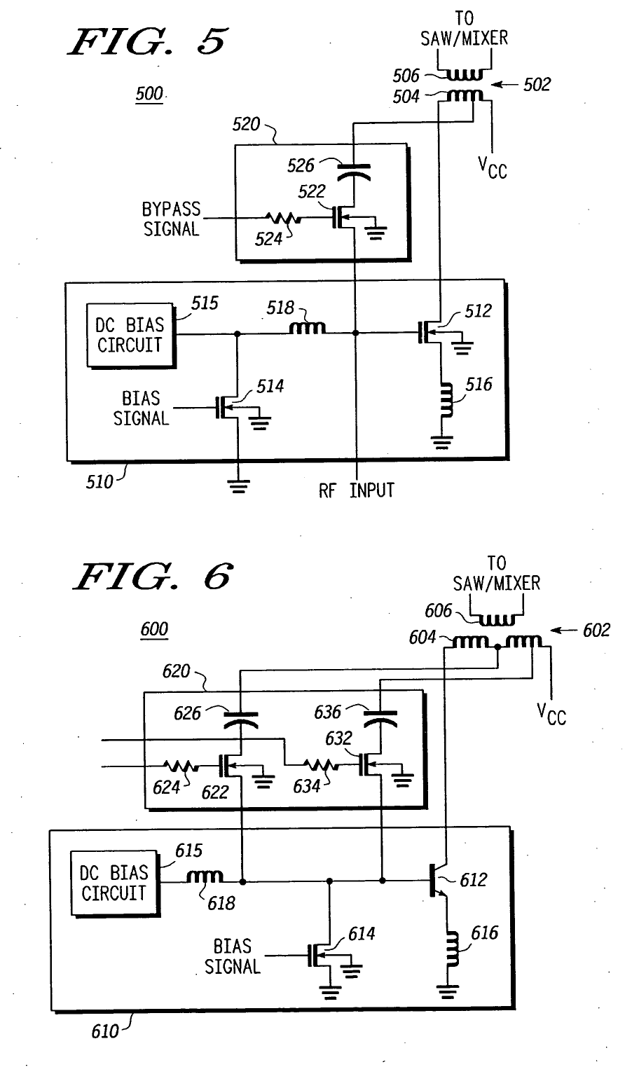

FIG. 5 illustrates another embodiment of a low noise amplifier of the present invention. As shown in FIG. 5, the low noise amplifier 500 contains a transformer 502, an active stage 510 and a bypass stage 520. The amplifier 500 has two modes: an active mode, in which the amplifier 500 provides gain to RF input signals supplied to it, and a bypass mode, in which the amplifier 500 does not provide gain to the RF input signals.

The transformer 502 has an input coil 504 and an output coil 506. The output coil 506 is connected to the SAW filter 114 or the mixer 124. One end of the input coil 504 is connected to a power supply (not shown) and the other end is connected to the active stage 510.

The active stage 510 contains a gain transistor 512, a DC bias circuit 515, a bias switch 514, and first and second inductors 516 and 518. Unlike the embodiment of FIG. 2, the gain transistor 512 in this embodiment is a MOSFET, rather than a BJT. The drain of the MOSFET 512 is connected to the other end of the input coil 504. The source of the MOSFET 512 is connected to ground through the first inductor 516. The RF input signals are supplied to the gate of the MOSFET 512. The bias circuit 514 provides DC biasing to the base of the MOSFET 512 through the second inductor 518 such that the MOSFET 512 is on in the active mode and is off in the bypass mode. The second inductor 518 provides a large impedance to the input signals supplied to the base of the MOSFET 512 so that the input signals are supplied to the transformer 502 without substantial signal loss.

The source of a MOSFET bias switch 514 is connected to ground, the drain is connected to the second inductor 518, and the gate is supplied with a bias on/off switch. The MOSFET bias switch 514 is turned on in the bypass mode such that one end of the second inductor 518 is grounded. The DC bias circuit 515 may be turned off in the bypass mode. Similarly, the MOSFET bias switch 514 is turned off in the active mode such that one end of the second inductor 518 is DC biased at the bias voltage provided by the DC bias circuit 515.

The bypass stage 520 contains MOSFET bypass switch 522, a resistor 524, and a capacitor 526. The gate of the bypass switch 522 is supplied with a bypass signal through the resistor 524. The resistor 524 decreases the current supplied to the gate of the bypass switch 522 when the amplifier 500 enters the bypass mode. The source of the bypass switch 522 is connected to the gate of the MOSFET 512 and the second inductor 518. The drain of the bypass switch 522 is connected to the input coil 504 of the transformer 502 through the capacitor 526, which blocks a DC voltage from being supplied to the transformer 502. More specifically, the drain of the bypass switch 522 taps the transformer 502 and is connected between the end of the input coil 504 connected to the MOSFET 512 and the end of the input 504 connected to the power supply.

When the amplifier 500 is in the active mode, the bypass switch 522 is turned off and the input signals are provided to the transformer 502 through the MOSFET 512. The MOSFET 512 provides gain for the input signals so that the output signals supplied to the mixer 106 are amplified. When the amplifier 500 is in the bypass mode, the MOSFET 512 is turned off and the input signals are provided to the transformer 502 through the bypass switch 522. The MOSFET bypass switch acts merely as a switch to provide the input signals to the transformer 502 in the bypass mode and does not provide the input signals with gain.

In the foregoing specification, the invention has been described with reference to specific embodiments. However, one of ordinary skill in the art appreciates that various modifications and changes can be made without departing from the scope of the present invention as set forth in the claims below. For example, although MOSFETs have been used, MISFETs (metal-insulator-semiconductor transistors) or other transistors may be used. Either NMOS or PMOS devices may be used as desired, although NMOS devices are faster and draw less current than PMOS devices. Accordingly, the specification and figures are to be regarded in an illustrative rather than a restrictive sense, and all such modifications are intended to be included within the scope of present invention. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

It is therefore intended that the foregoing detailed description be regarded as illustrative rather than limiting, and that it be understood that it is the following claims, including all equivalents, that are intended to define the spirit and scope of this invention. Nor is anything in the foregoing description intended to disavow scope of the invention as claimed or any equivalents thereof.

We claim:

1. An amplifier comprising:
a first transistor;
a first switch; and
a transformer having an input coil to which the first transistor and first switch are coupled at different points, the amplifier having an active mode in which current is drawn by the amplifier and a bypass mode in which substantially no current is drawn by the amplifier compared with the active mode.

2. The amplifier of claim 1, wherein the first switch is connected to the first transistor and the transformer such that an input impedance of the amplifier is substantially the same in the active mode and in the bypass mode.

3. The amplifier of claim 1, wherein the first switch is connected between opposing ends of the transformer and the first transistor is connected to one of the ends of the transformer.

4. The amplifier of claim 1, further comprising a bias circuit that DC biases the first transistor to turn on the first transistor in the active mode, the first transistor turned off in the bypass mode.

5. The amplifier of claim 1, wherein one end of the first switch is connected to an input terminal of the first transistor.

6. The amplifier of claim 1, wherein the first transistor comprises a bipolar junction first transistor (BJT) and the first switch comprises a metal-oxide-semiconductor (MOS) device.

7. The amplifier of claim 1, wherein the first transistor and first switch each comprises a metal-oxide-semiconductor (MOS) device.

8. The amplifier of claim 1, wherein the only mode in which the amplifier has gain is the active mode.

9. The amplifier of claim 1, further comprising a second transistor and a second switch coupled to the input coil at different points and symmetric with the first transistor and first switch around a center of the input coil.

10. An electronic device comprising the amplifier of claim 1.

11. An amplifier comprising:
a first transistor;
a first switch; and
a transformer having an input coil to which the first transistor and first switch are coupled at different points such that an input impedance of the amplifier remains substantially constant independent of the gain supplied by the amplifier.

12. The amplifier of claim 11, wherein the first switch is connected between opposing ends of the transformer and the first transistor is connected to one of the ends of the transformer.

13. The amplifier of claim 11, wherein one end of the first switch is connected to an input terminal of the first transistor.

14. The amplifier of claim 11, wherein the first transistor comprises a bipolar junction first transistor (BJT) and the first switch comprises a metal-oxide-semiconductor (MOS) device.

15. The amplifier of claim 11, wherein the first transistor and first switch each comprises a metal-oxide-semiconductor (MOS) device.

16. The amplifier of claim 11, wherein the amplifier only has one mode with gain.

17. The amplifier of claim 11, further comprising a second transistor and a second switch coupled to the input coil at different points and symmetric with the first transistor and first switch around a center of the input coil.

18. A receiver comprising the amplifier of claim 11.

19. A method of impedance matching different modes of an amplifier comprising a transformer, the method comprising:
designing an amplifier with desired characteristics;
determining an input impedance of the amplifier; and
coupling an input of a gain stage of the amplifier to a point between ends of the transformer such that the input impedance of the amplifier is substantially independent of the mode of the amplifier.

20. The method of claim 19, further comprising connecting a first transistor of the gain stage to a first end of the transformer.

21. The method of claim 20, further comprising connecting the input of the gain stage between the ends of the transformer through a switch.

22. The method of claim 20, further comprising connecting a second transistor of the gain stage to a second end of the transformer.

23. The method of claim 22, further comprising connecting the input of the gain stage to multiple locations between the ends of the transformer through switches such that the first and second transistors and switches are symmetric around a center of the input transformer.

24. The method of claim 21, wherein the first transistor comprises a bipolar junction first transistor (BJT) and the first switch comprises a metal-oxide-semiconductor (MOS) device.

25. The method of claim 21, wherein the first transistor and first switch each comprises a metal-oxide-semiconductor (MOS) device.

26. The method of claim 19, further comprising coupling the input of the gain stage between ends of the transformer such that the gain stage is bypassed in a bypass mode.

27. The method of claim 26, further comprising limiting the number of modes of the amplifier to a single active mode, in which the amplifier has gain, and the bypass mode, in which the amplifier has substantially no gain.
